(19) United States
(12) Patent Application Publication
(10) Pub. No.: US 2026/0198257 A1
(43) Pub. Date: Jul. 9, 2026

(54) JIG FOR WAFER ETCHING AND WAFER ETCHING METHOD

(71) Applicant: SK SILTRON CO., LTD., Gumi-si (KR)

(72) Inventor: Yong Jae CHOI, Gumi-si (KR)

(21) Appl. No.: 19/426,653

(22) Filed: Dec. 19, 2025

(30) Foreign Application Priority Data
Jan. 6, 2025 (KR) 10-2025-0001859

(51) Int. Cl. H10P 72/10; H10P 50/64; H10P 72/00

(52) U.S. Cl. CPC H10P 72/127; H10P 50/642; H10P 72/0426; H10P 72/123

(57) ABSTRACT

The present disclosure relates to a jig for wafer etching and a wafer etching method, which are capable of preventing the wafer from being damaged while performing uniform etching. According to an embodiment, provided is a jig for wafer etching, which includes a connection part mounted on a transferring robot and a rotating device, a shaft provided lengthily below the connection part, and a frame provided below the shaft and provided with a plurality of inclined slots through which wafers are loaded in a downwardly inclined direction.

### CROSS-REFERENCE TO RELATED APPLICATIONS

The present application claims priority under 35 U.S.C. 119 and 35 U.S.C. 365 to Korean Patent Application No. 10-2025-0001859 (filed on January 6, 2025), which is hereby incorporated by reference in its entirety.

### BACKGROUND

The present disclosure relates to a jig for wafer etching and a wafer etching method, which are capable of preventing the wafer from being damaged while performing uniform etching.

Wafers, which are commonly used as materials for manufacturing semiconductor elements, may be compound semiconductor substrates made of various materials such as silicon substrates, sapphires, GaN, SiGe, etc.

In the case of the silicon substrates, etching is performed to remove or mitigate mechanical damage caused to the wafers and to ensure stability of flatness before carrying out polishing processes.

Even in the case of the sapphire substrate, etching is performed to remove mechanical damage the substrate surface, ensure stability of flatness, or identify defects.

An apparatus for wafer etching, which is disclosed in Korean Patent Registration No. 2085941 (filed on August 14, 2018) includes: a main body member; an etching member configured to provide an etching process to the main body member, wherein an etchant is injected upward using an injection part having an outlet for the etchant, which is provided upward, to etch the wafer; and a wafer supply member configured to mount the wafer using a fixed jig provided adjacent to a side of the etching member, wherein the fixed jig is configured to so that an etching surface of the wafer is disposed downward from an upper portion of the injection part, and is configured to supply and support the wafter toward the etching space, into which the etchant is injected, to perform an etching operation while injecting the etchant through the injection part.

To immerse the wafer into the etchant, a movable jig detachably mounts the wafer on the fixed jig, and the fixed jig rotates the fixed jig in place using rotational power transmitted to a driving shaft.

Thus, since the wafer is rotated during the etching process, the etchant does not remain on the surface of the wafer to prevent surface defects such as stains on the wafer surface, which are caused by the etchant.

However, according to the related art, even if the wafer is fixed by minimizing a fixed area through an additional jig, the wafer may be damaged due to applying of a pressure to the wafer. In addition, since a portion of the surface of the wafer is covered by the jig, it is difficult to perform the uniform etching.

### SUMMARY

Objects of embodiments are to solve the above-described limitations and other limitations.

Embodiments provide a jig for wafer etching, which is capable of preventing the wafer from being damaged while performing uniform etching.

In one embodiment, a jig for wafer etching includes: a connection part mounted on a transferring robot and a rotating device; a shaft provided lengthily below the connection part; and a frame provided below the shaft and provided with a plurality of inclined slots through which wafers are loaded in a downwardly inclined direction.

The frame may be made of a nickel or alumina material.

The frame may be mounted to be rotatable with respect to the shaft.

The frame may include: an upper plate connected to a lower end of the shaft; a lower plate spaced horizontally below the upper plate; two pairs of seating rods arranged vertically between the upper plate and the lower plate to hold outer circumferential ends of wafers loaded to be inclined downward; and at least one pair of guide rods arranged vertically between the upper plate and the lower plate and disposed in a direction in which the wafers are loaded.

The seating rods may include a plurality of seating slots spaced a predetermined distance from each other in a vertical direction to hold the outer circumferential ends of the wafers and provided to be inclined downward.

The guide rods may include a plurality of guide slots spaced a predetermined distance from each other in a vertical direction to guide the loading of the wafers and provided to be inclined downward.

The guide rods may be disposed to be spaced apart from each other by as much as a diameter of each of the wafers so that the guide slots face each other.

The guide rods may be installed to pass through the upper plate and the lower plate so as to be elevatable by a predetermined distance.

The guide rods may be configured to load the wafers as the guides rods ascend when the lower plate is supported on the bottom and be configured to prevent the wafers from being separated as the guide rods descend due to their own weight when the lower plate is spaced apart from the bottom.

In another embodiment, a wafer etching method may include: a first process of seating a jig for wafer etching on a loading part to prepare loading of wafers; a second process of loading the wafers seated on a cassette into a plurality of inclined slots, which are provided to be inclined downward, on the jig for the wafer etching; a third process of allowing the jig for the wafer etching to ascend so as to prevent the wafers from being separated; and a fourth process of inputting the jig for the wafer etching into an etchant.

The first process may include a process of allowing guide rods provided at inlets of the inclined slots to ascend to a position, to which the wafers are loaded, as the jig for the wafer etching is seated on the loading part.

The second process may include a process of allowing outer circumferential portions of the wafers to pass through the guide rods of the jig for the wafer etching and to be seated on the inclined slots forming the inclined slots.

The third process may include a process of allowing the guide rods of the jig for the wafer etching to a position at which the wafers are prevented from being separated as the jig for the wafer etching ascends.

The fourth process may include a process of rotating the seating rods and the guide rods of the jig for the wafer etching and the wafers seated to be inclined downward within the etchant.

The details of one or more embodiments are set forth in the accompanying drawings and the description below. Other features will be apparent from the description and drawings, and from the claims.

### BRIEF DESCRIPTION OF THE DRAWINGS

FIG. 1 is a front view of a jig for wafer etching according to an embodiment.

FIG. 2 is a side view of the jig for the wafer etching according to an embodiment.

FIG. 3 is a perspective view of the jig for the wafer etching according to an embodiment.

FIG. 4 is an enlarged perspective view illustrating a frame of the jig for the wafer etching according to an embodiment.

FIG. 5 is a flowchart illustrating a wafer etching method according to an embodiment.

### DETAILED DESCRIPTION OF THE EMBODIMENTS

Hereinafter, exemplary embodiments will be described in detail with reference to the accompanying drawings.

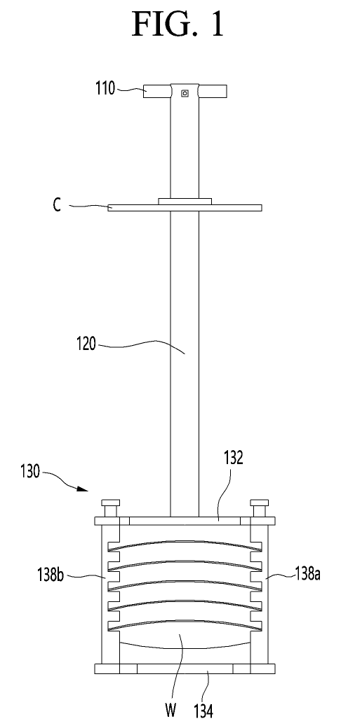

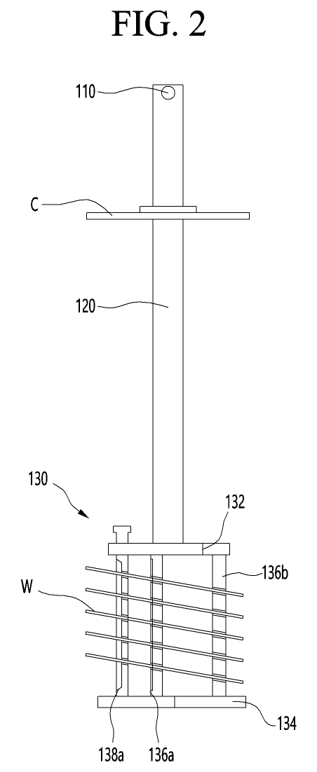

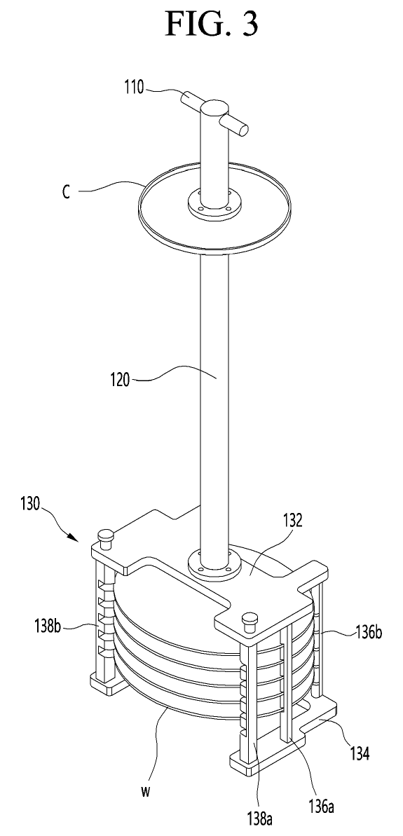

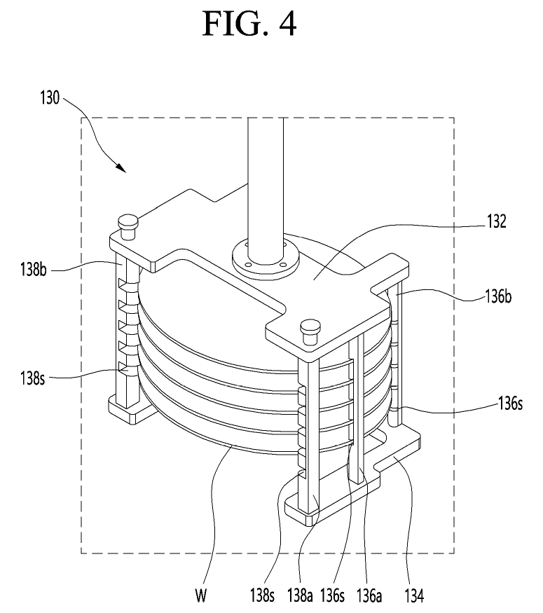

FIGS. 1 to 3 are front, side, and perspective views of a jig for wafer etching according to an embodiment, respectively, and FIG. 4 is an enlarged perspective view illustrating a frame of the jig for the wafer etching according to an embodiment.

As illustrated in FIGS. 1 to 4, a jig for wafer etching according to an embodiment may include a connection part 110 having a short-axis shape and disposed horizontally, a shaft 120 connected lengthily vertically to a lower portion of the connection part 110, and a frame 130 having a plurality of inclined slots, into which wafers W are loaded in a downwardly inclined direction, at a lower side of the shaft 120.

The connection part 110, the shaft 120, and the frame 130 may be made of nickel or alumina materials having chemical resistance and corrosion resistance even when immersed in an etchant such as KOH.

The connection part 110 may be in the form which is capable of being mounted on a transfer robot or a rotating device, e.g., in the form of a rod, but is not limited thereto.

The shaft 120 may be vertically disposed to connect an intermediate point of the connection part 110 to an upper central portion of the frame 130. The shaft 120 may serve as a central axis for transmitting rotational force when rotating the frame 130.

A cover part C having a circular plate shape may be horizontally disposed on an upper circumference of the shaft 120. Here, when a lower portion of the shaft 120 and the frame 130 are immersed in an etchant, the cover part C may prevent the etchant from splashing upward to prevent a transfer robot or a rotating device from being damaged by the etchant.

The frame 130 may be provided with a plurality of inclined slots stacked vertically to communicate the wafers W seated on a cassette as they are. The frame 130 may include an upper plate 132 connected to a lower end of the shaft 120, a lower plate 134 spaced horizontally below the upper plate 132, two pairs of seating rods 136a and 136b arranged vertically between the upper plate 132 and the lower plate 134 to hold outer circumferential ends of the wafers W loaded to be inclined downward, and at least one pair of guide rods 138a and 138b arranged vertically between the upper plate 132 and the lower plate 134 and disposed in the direction in which the wafers W are loaded.

The upper plate 132 may have a plate shape with a minimum surface area for installing a lower end of the shaft 120, upper ends of the seating rods 136a and 136b, and upper ends of the guide rods 138a and 138b. Similarly, the lower plate 134 may also have a plate shape with a minimum surface area for installing lower ends of the seating rods 136a and 136b and lower ends of the guide rods 138a and 138b, and thus, the upper plate 132 and the lower plate 134 may be configured in various manners.

Four seating rods 136a and 136b may support the outer circumferential ends of the wafers W, which are loaded to be inclined downward, at both sides of the lower portion. The settling rods 136a and 136b may be fixed to be perpendicular to the upper plate 132 and the lower plate 134 and may be disposed at four circumferential points corresponding to the outer circumferential ends of the wafers W.

The seating rods 136a and 136b may be provided with a plurality of seating slots 136s, and the seating slots 136s may be spaced a predetermined distance from each other in inner surfaces of the seating rods 136a and 136b in the vertical direction and be provided to be inclined downward. The seating slots 136s may be provided to support the wafers, which are loaded in a direction that is inclined downward by about 15° with respect to a horizontal plane, but is not limited thereto.

Two guide rods 138a and 138b may guide the wafers W which are loaded to be inserted downward toward the seating rods 136a and 136b or may prevent the wafers W from being separated. The guide rods 138a and 138b may be connected to be perpendicular to the upper plate 132 and the lower plate 134 so as to be installed to be elevatable by a predetermined distance and may be provided to be spaced apart from each other by a predetermined distance that is larger than a diameter of each of the wafers W in the direction in which the wafers W are loaded.

The guide rods 138a and 138b may be provided with a plurality of guide slots 138s, and the guide slots 138s may be provided to be spaced a predetermined distance from each other in the vertical direction and inclined downward in surface of the guide rods 138a and 138b, which face each other.

An operation state of the jig for the wafer etching, which is configured as described above, are as follows.

When the jig is seated on the bottom through a moving robot, the lower plate 134 may be in contact with the bottom to allow the guide rods 138a and 138b to ascend, and thus, the guide slots 138s and the seating slots 136s may be disposed in a row in the downwardly inclined direction. When the wafers W are input through the guide slots 138s in the downwardly inclined direction, both sides of the lower portion of the outer circumferential ends of the wafers W, which are loaded to be inclined downward, may be supported in the seating slots 136s.

When the moving robot allows the jig to ascend so as to move above an etching bath, the guide rods 138a and 138b, which are separated from the bottom, may descend due to their own weight, and the guide slots 138s may be misaligned with the seating slots 136s in a line that is inclined downward. The outer circumferential ends of the wafers W supported in the seating slots 136s may be supported by the guide rods 138a and 138b to prevent the wafers W from being separated from the frame 130.

The moving robot may immerse the jig, on which the wafers W are seated, in the etchant inside the etching batch, and then, the rotating device may rotate the jig while performing the etching process. During the etching process, since the wafers W rotate around the shaft 120 in the downwardly inclined state, the wafers W may be stably held to prevent the wafers W from being damaged and also to serve to agitate the etchant, thereby further improving the etching performance.

In addition, since the frame 130 immersed in the etchant is configured to have a minimal volume with the upper plate 132, the lower plate 134, the seating rods 136a and 136b, and the guide rods 138a and 138b, waste of the etchant may be minimized.

In addition, since the outer circumferential ends of the wafers W are in contact with only the seating slots 136s and the guide rods 138a and 138b over a minimal surface area, the etchant may be uniformly transferred to the surfaces of the wafers to uniformly etch the surfaces of the wafers.

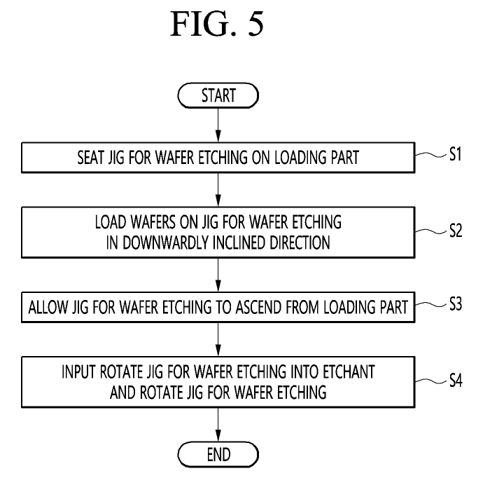

FIG. 5 is a flowchart illustrating a wafer etching method according to an embodiment.

According to a wafer etching method according to an embodiment, a jig for wafer etching may be seated on a loading part to prepare for loading wafers (see S1).

The jig may be provided with downwardly inclined slots, and a pair of guide rods may be provided elevatably at inlets of the inclined slots. When the jig is seated on the floor, the guide rods come into contact with the floor and rise, and wafers can be loaded through the guide slots provided on the guide rods.

Next, the wafers seated on a cassette are loaded into a plurality of inclined slots provided on a jig for wafer etching in a downwardly inclined manner (see S2).

In the state in which the guide rods ascend, the wafers horizontally accommodated in the cassette may be loaded onto the jig in a downwardly inclined direction. The wafers loaded downwardly and inclinedly between the guide rods may be seated on two pairs of seating rods, and thus, the seating slots provided on the seating rods may hold both lower sides of the wafers that are downwardly inclined. In the state in which the guide rods ascend, the guide slots and the seating slots may be disposed in a row in the downwardly inclined direction to allow the downwardly inclined wafers to be loaded.

Next, the jig for the wafer etching may ascend from a loading part to prevent the wafers from being separated (see S3).

When the jig is separated from the bottom, the guide rods may descend by a load, and the guide slots may be misaligned with the seating slots from the downwardly inclined line. Outer circumferential ends of the wafers supported to be downwardly inclined in the sealing slots may be supported by the guide rods to prevent the wafers from being separated from the jig and being damaged.

Next, the jig for the wafer etching may be immersed in an etchant to rotate (see S4).

The wafers mounted to be downwardly inclined on the jig may rotate within the etchant to improve etching performance and ensure uniform etching.

According to the embodiments, since the jig for the wafer etching rotates within the etchant while holding the wafer in the downwardly inclined state, the wafer may be stably held during the etching process to prevent the wafer from being damaged. Furthermore, the etchant may be stirred to improve the etching performance.

In addition, the jig for the wafer etching may be simply configured to have only the minimum volume, thereby maximally reducing the waste of the etchant and be in contact with the minimum surface area of only the outer ends of the wafers to uniformly etch the surface of the wafer.

The above-disclosed subject matter is to be considered illustrative, and not restrictive, and the appended claims are intended to cover all such modifications, enhancements, and other embodiments, which fall within the true spirit and scope of the present invention.

Thus, the embodiment of the present invention is to be considered illustrative, and not restrictive, and the technical spirit of the present invention is not limited to the foregoing embodiment.

Therefore, the scope of the present invention is defined not by the detailed description of the invention but by the appended claims, and all differences within the scope will be construed as being included in the present invention.

What is claimed is:

1. A jig for wafer etching, comprising:
a connection part mounted on a transferring robot and a rotating device;
a shaft provided lengthily below the connection part; and
a frame provided below the shaft and provided with a plurality of inclined slots through which wafers are loaded in a downwardly inclined direction.

2. The jig according to claim 1, wherein the frame is made of a nickel or alumina material.

3. The jig according to claim 1, wherein the frame is mounted to be rotatable with respect to the shaft.

4. The jig according to claim 1, wherein the frame comprises:
an upper plate connected to a lower end of the shaft;
a lower plate spaced horizontally below the upper plate;
two pairs of seating rods arranged vertically between the upper plate and the lower plate to hold outer circumferential ends of wafers loaded to be inclined downward; and
at least one pair of guide rods arranged vertically between the upper plate and the lower plate and disposed in a direction in which the wafers are loaded.

5. The jig according to claim 4, wherein the seating rods comprise a plurality of seating slots spaced a predetermined distance from each other in a vertical direction to hold the outer circumferential ends of the wafers and provided to be inclined downward.

6. The jig according to claim 4, wherein the guide rods comprise a plurality of guide slots spaced a predetermined distance from each other in a vertical direction to guide the loading of the wafers and provided to be inclined downward.

7. The jig according to claim 6, wherein the guide rods are disposed to be spaced apart from each other by as much as a diameter of each of the wafers so that the guide slots face each other.

8. The jig according to claim 7, wherein the guide rods are installed to pass through the upper plate and the lower plate so as to be elevatable by a predetermined distance.

9. The jig according to claim 8, wherein the guide rods are configured to load the wafers as the guides rods ascend when the lower plate is supported on the bottom and are configured to prevent the wafers from being separated as the guide rods descend due to their own weight when the lower plate is spaced apart from the bottom.

10. A wafer etching method comprising:
a first process of seating a jig for wafer etching on a loading part to prepare loading of wafers;
a second process of loading the wafers seated on a cassette into a plurality of inclined slots, which are provided to be inclined downward, on the jig for the wafer etching;
a third process of allowing the jig for the wafer etching to ascend so as to prevent the wafers from being separated; and
a fourth process of inputting the jig for the wafer etching into an etchant.

11. The wafer etching method according to claim 10, wherein the first process comprises a process of allowing guide rods provided at inlets of the inclined slots to ascend to a position, to which the wafers are loaded, as the jig for the wafer etching is seated on the loading part.

12. The wafer etching method according to claim 11, wherein the second process comprises a process of allowing outer circumferential portions of the wafers to pass through the guide rods of the jig for the wafer etching and to be seated on the inclined slots forming the inclined slots.

13. The wafer etching method according to claim 12, wherein the third process comprises a process of allowing the guide rods of the jig for the wafer etching to a position at which the wafers are prevented from being separated as the jig for the wafer etching ascends.

14. The wafer etching method according to claim 13, wherein the fourth process comprises a process of rotating the seating rods and the guide rods of the jig for the wafer etching and the wafers seated to be inclined downward within the etchant.
